(19) United States
(12) Patent Application Publication
(10) Pub. No.: US 2010/0279458 A1
(43) Pub. Date: Nov. 4, 2010

(54) PROCESS FOR MAKING PARTIALLY TRANSPARENT PHOTOVOLTAIC MODULES

(75) Inventors: Hsieh-Hsin YEH, Taipei (TW); Chi Lai LEE, PingZhen City (TW); Hsuan-Ping CHEN, Qiaotou Township (TW)

Correspondence Address: SUGHRUE MION, PLLC, 2100 PENNSYLVANIA AVENUE, N.W., SUITE 800, WASHINGTON, DC, 20037, US

(73) Assignee: DU PONT APOLLO LTD., New Territories (HK)

(21) Appl. No.: 12/769,324

(22) Filed: Apr. 28, 2010

Related U.S. Application Data
(60) Provisional application No. 61/173,851, filed on Apr. 29, 2009.

(51) Int. Cl. H01L 31/18

(52) U.S. Cl. 438/98; 257/E31.126

(57) ABSTRACT

A process for making a partially transparent photovoltaic cell or a partially transparent photovoltaic module comprising series-connected or parallel-connected photovoltaic cells comprises the step of forming a patterned back electrode(s) by screen printing, jet printing, roll-to-roll processing or depositing through a shadow mask with openings. The pattern of the back electrode is determined at the same time when the back electrode is disposed, such that the complexity and cost of the process can be reduced.

### FIELD OF THE INVENTION

The present invention relates to partially transparent photovoltaic cells and modules and the process for their manufacture.

### BACKGROUND OF THE INVENTION

A photovoltaic cell converts light energy into electric energy. A typical photovoltaic cell includes a transparent substrate, and a front electrode, a photoelectric conversion element and a back electrode disposed in order on the substrate. Incoming light is transmitted to the photoelectric conversion layer through the substrate and the front electrode. The front electrode is made of transparent conductive oxide, such as tin oxide, indium oxide or indium tin oxide, for transmitting the incoming light into the photoelectric conversion element. The photoelectric conversion element is made of amorphous silicon, single crystal silicon, polycrystalline silicon, cadmium telluride and other semiconductor material, with a p-i-n or p-n junction structure, for converting light energy into electric energy. The back electrode is made of a metal, for example, Al, Ag, TiAg, Ni, Au or Cr and generally covers the entire surface of the photovoltaic cell. Such a back electrode prevents light from passing through the cell.

In certain applications, for example, when used in vehicles or buildings as windows, sun screens, canopies, roofs, etc., it is desirable that the photovoltaic cell permits partial light transmission through the cell. Using transparent conductive oxide as the back electrode is a way to make the photovoltaic cell transparent. However, transparent conductive oxide has higher resistance and is more expensive as compared to the conventional metal back electrode. U.S. Pat. No. 4,795,500 disclosed a partially transparent photovoltaic device comprising a metal back electrode having a plurality of holes for transmission of light. The portion of the area of the holes determines the transmittance factor of light. According to U.S. Pat. No. 4,795,500, the holes are formed by selective etching by a photolithographic process. The photolithographic process makes the photovoltaic device manufacture process complicated. U.S. Pat. No. 6,858,461 disclosed a process for making a partially transparent photovoltaic module comprising laser scribing a plurality of laser scribes through the metal back electrode so that light can pass through the module where the metal is removed. However, during the laser operation, dust particles will be produced, and hence, a cleaning step is required. In addition, as disclosed in U.S. Pat. No. 6,858,461, if a metal having high reflectivity, such as Al, is used as a back electrode, it is difficult to prevent a laser operation at a power density necessary for direct ablation of the back electrode with high reflectivity from damaging the underlying semiconductor material, which may result in the electrical shorting of the photovoltaic cell. To solve the problem, the laser should be operated at a power level that will ablate the semiconductor material to scribe the metal back electrode layer and the underlying semiconductor material at the same time. Since a portion of the photoelectric conversion semiconductor material is sacrificed, there will be an additional 6% to 10% power loss of the photovoltaic cell.

In view of the above, it is desirable to have a simple and cost-efficient process for making a partially transparent photovoltaic cell. It is also desirable to have a partially transparent photovoltaic cell that provides not only enough transmission of light but also good photoelectric conversion.

### SUMMARY OF THE INVENTION

The present invention provides a process for making a partially transparent photovoltaic cell comprising a transparent front electrode, a photoelectric conversion element and a patterned back electrode disposed in order on a transparent substrate, said process comprising forming the back electrode by screen printing, jet printing, roll-to-roll processing or depositing through a shadow mask with openings.

The present invention also provides a process for making a partially transparent photovoltaic module comprising series-connected or parallel-connected photovoltaic cells, each of the photovoltaic cells comprising a transparent front electrode, a photoelectric conversion element and a patterned back electrode disposed in order on a transparent substrate, said process comprising forming the patterned back electrodes by screen printing, jet printing, roll-to-roll processing or depositing through a shadow mask with openings.

The present invention further provides a process for making a partially transparent photovoltaic module comprising series-connected photovoltaic cells, said process comprising the steps of:

(a) providing a transparent substrate;

(b) forming transparent front electrodes on the substrate, wherein the transparent front electrodes are separated from each other by first grooves;

(c) forming photoelectric conversion elements on the transparent front electrodes and the first grooves, wherein the photoelectric conversion elements are separated from each other by second grooves disposed on the transparent front electrodes; and

(d) forming patterned back electrodes by screen printing, jet printing, roll-to-roll processing or depositing through a shadow mask with openings, wherein the patterned back electrodes are separated from each other by third grooves.

### BRIEF DESCRIPTION OF THE DRAWING

FIG. 1 is a schematic review of a photovoltaic cell made according to the process of the present invention.

FIG. 2 shows an embodiment of pattern with circular holes according to the present invention.

FIGS. 3(a) and 3(b) illustrate a process for making a partially transparent photovoltaic module according to one embodiment of the present invention.

FIG. 3(c) is a top view of the pattern of the patterned metal layer of FIG. 3(b).

FIGS. 4(a) to 4(c) are schematic reviews of the patterns of the patterned metal layer according to the present invention.

FIGS. 5(a) and (b) illustrate a process for making a partially transparent photovoltaic module according to the present invention.

FIG. 5(c) is a top view of the patterned back electrodes of the photovoltaic module of FIG. 5(b).

### DETAILED DESCRIPTION OF THE INVENTION

The present invention is illustrated below in detail by the embodiments with reference to the drawings, which are not intended to limit the scope of the present invention. It will be apparent that any modifications or alterations that can easily be accomplished by those having ordinary skill in the art fall within the scope of the disclosure of the specification.

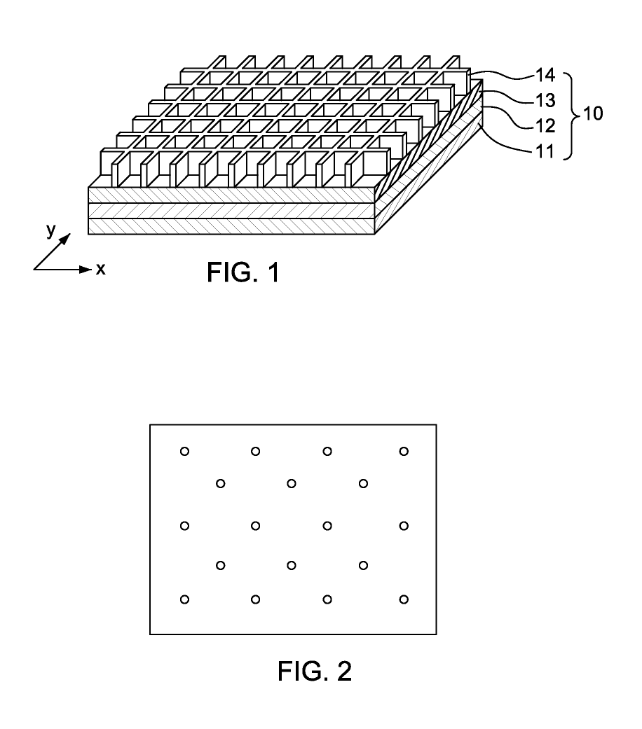

FIG. 1 illustrates a photovoltaic cell made according to the process of the present invention. As shown in FIG. 1, the photovoltaic cell 10 comprises a front electrode 12, a photoelectric conversion element 13 and a patterned back electrode 14 disposed in order on a transparent substrate 11. The transparent substrate 11 of the present invention can be any substrate known to persons having ordinary skill in the art, such as plastic or glass. The front electrode 12 can be made of any suitable material known to persons having ordinary skill in the art, for example, but is not limited to, transparent conductive oxide, such as tin oxide, indium oxide or indium tin oxide. The photoelectric conversion element 13 can be made of a semiconductor material known in the art, such as amorphous silicon, single crystal silicon, polycrystalline silicon, cadmium telluride and the like, according to any of conventional processes. The structure of the photoelectric conversion element 13 is not specifically limited and can be, for example, a p-i-n or p-n junction. The material of the patterned back electrode 14 can be a metal, a transparent conductive oxide (TCO), or a combination thereof, and preferably, the patterned back electrode is composed of a patterned metal layer and an optional TCO layer with or without pattern. The species of the metal used in the present invention is known in the art for example, but not limited, Al, Ag, TiAg, Ni, Au, Cr or a alloy thereof, and the species of the TCO used in the present invention is also known in the art, for example, but not limited, aluminum doped zinc oxide (AZO), gallium doped zinc oxide (GZO), or both aluminum and gallium doped zinc oxide (AGZO).

In the process of the present invention, the stack of the transparent substrate 11, the front electrode 12, and the photoelectric conversion element 13 can be made according to any suitable process known in the art, and then the patterned back electrode 14 is formed on the photoelectric conversion element 13 by screen printing, jet printing, roll-to-roll processing or depositing through a shadow mask with openings. The patterned back electrode is designed so that at least a portion of the photoelectric conversion element is uncovered by the back electrode and light can transmit the photovoltaic cell therethrough. Contrary to the conventional processes for making a partially transparent photovoltaic cell or module in which an etching, laser scribing or other pattering step is conducted after the formation of the back electrode so as form a specific pattern for the transmission of light, the process of the present invention can directly form a patterned back electrode. According to the present invention, the pattern of the back electrode layer is determined at the same time when the back electrode layer is disposed, such that the complexity and cost of the process can be reduced.

It is known that transparent conductive oxides can be directly disposed on the photoelectric conversion element as a back electrode of a partially transparent photovoltaic cell without additional patterning step, due to their transparency. However, transparent conductive oxides are more expensive than metals. Furthermore, if the back electrode is made of TCO only, a thick TCO layer must be used so as to achieve better electrical performance, thereby increasing the cost. According to one preferred embodiment of the present invention, the patterned back electrode is composed of a patterned metal layer and an optionally TCO layer with or without pattern. In this embodiment, it is unnecessary to use a thick TCO layer so that the cost can be reduced; and the pattern on the metal layer can be various since the TCO layer can be formed with any suitable pattern to keep the whole back electrode being electrically-connected.

In this embodiment, the patterned metal layer is formed on the photoelectric conversion element by screen printing, jet printing, roll-to-roll processing or depositing through a shadow mask with openings so as to have desired pattern, and then a TCO layer is disposed on the patterned metal layer. The TCO layer can be disposed on the patterned metal layer by any suitable process known in the art, such as depositing, or by the process according to the present invention, i.e., screen printing, jet printing, roll-to-roll processing or depositing through a shadow mask with openings. In addition, although a patterned back electrode made of a TCO layer alone may not be desirable due to the cost of the transparent conductive oxides, it should be understood that this embodiment or any modifications or alterations based on this embodiment still fall within the scope of the present invention.

In the present invention, when the patterned back electrode comprises a patterned metal layer and an optional TCO layer with or without pattern, an open ratio is defined as the area of the portion uncovered by the patterned metal layer divided by the total area of the back electrode including the portion uncovered by metal. If the open ratio is too low, the photovoltaic cell or module cannot transmit light efficiently; if the open ratio is too high, the electrical resistance of the back electrode will increase. However, the range of the open ratio is not specifically limited because the open ratio may vary in a broad range, for example, from 50% to 90% depending on the species of the metal used.

The pattern on the back electrode will affect the open ratio, so as to affect the efficiencies of light transmission and photoelectric conversion. According to the present invention, the pattern can be made by screen printing, jet printing, roll-to-roll processing or depositing through a shadow mask with openings at the same time when the back electrode is formed. The type of pattern that can be used in the present invention is various, for example, but is not limited to, web-like pattern; pattern with holes, for example, circular holes or rectangular holes; pattern with linear or non-linear openings for example, stripe-like openings; or pattern with any other type of openings. If needed, trademarks can also be formed as the pattern or part of the pattern of the back electrode according to the above methods.

An embodiment of web-like pattern according to the present invention is shown in FIG. 1 (back electrode 14). An embodiment of pattern with circular holes according to the present invention is shown in FIG. 2.

According to the present invention, by screen printing, jet printing, roll-to-roll processing or depositing through a shadow mask with openings, the pattern of the back electrode can be determined at the same time when the back electrode is formed. The methods of forming a desired pattern on a substrate by screen printing, jet printing, roll-to-roll processing or shadow mask depositing are known in the art and widely used in many fields. However, the inventors of the present invention found that these methods are particularly suitable in the manufacture of the back electrode of partially transparent photovoltaic cells or modules. By using these methods, it is easy to form a patterned back electrode capable of transmitting light, without additional patterning step, such that the complexity and cost of the process can be reduced; and the pattern of the back electrode can be simply modified, such that the efficiencies of light transmission and photoelectric conversion can be adjusted according to the species of the materials of the back electrode, the requirement of the end-use, etc. According to the present invention, a corresponding shape of the desired pattern is pre-designed on the screen, roll, and mask; and a conductive material, such as metal or TCO, is then used to form a back electrode with a desired pattern by screen printing, roll-to-roll processing, and shadow mask depositing, respectively. According to the present invention, when a jet printing process is chosen, the pattern is determined by controlling the route of the printhead and the patterned back electrode is formed by jet printing.

According to the present invention, the patterned back electrode is formed by screen printing, jet printing, roll-to-roll processing or depositing through a shadow mask with openings, among which depositing through a shadow mask with openings is preferred. For the purpose of depositing a patterned back electrode, a shadow mask having openings of the desired pattern is used, so that the back electrode is formed with the pattern as defined by the openings.

The shadow mask and the deposition device are well known in the art and commonly used in the manufacture of displays, for example, in the manufacture of organic light emitting diode for the organic sub-pixel and cathode window patterning. The disclosure of the shadow mask and deposition device and the process using the same can be found in U.S. Pat. No. 7,442,258 and US 2008/0000420. Recently, US 2008/0145521 disclosed a shadow mask includes a rigid frame and a plurality of openings separated by crossbars, and a method for fabricating a solar-cell module by said shadow mask in a deposition process. In the method of US 2008/0145521, the shadow mask is used for depositing the photoelectric conversion elements and the back electrodes of a solar-cell module, each of the photoelectric conversion elements is defined by the openings of the shadow mask and separated from each other by gaps formed due to the sheltering of crossbars, and so do the back electrodes. The distance between the photoelectric conversion elements and the back electrodes can be adjusting by selecting the widths of the crossbars ranging from 0.02 mm to 2 mm. By changing the relative position of the shadow mask and the substrate, the method of US 2008/0145521 can fabricate multiple layers in photovoltaic cells continuously, so that it is simpler and cleaner as compared to some conventional processes. The inventors of the present invention further found that a shadow mask is particularly suitable in the manufacture of a partially transparent photovoltaic cell or module for depositing a patterned back electrode for transmitting light. By designing the size and shape of the openings on the shadow mask and then depositing a metal or TCO through the openings, a patterned back electrode can be formed with the pattern defined by the openings.

According to the present invention, the step of shadow mask deposition can be conducted one or more times to form specific patterns. For example, the web-like pattern of FIG. 1 can be produced by depositing a metal or TCO material in x-direction in a first shadow mask deposition step and then depositing said metal or TCO material in y-direction in a second shadow mask deposition step. Since the openings on the shadow mask can be designed with any suitable type and size, the pattern on the back electrode can be modified as needed, depending on the requirement for light transmission and photoelectric conversion.

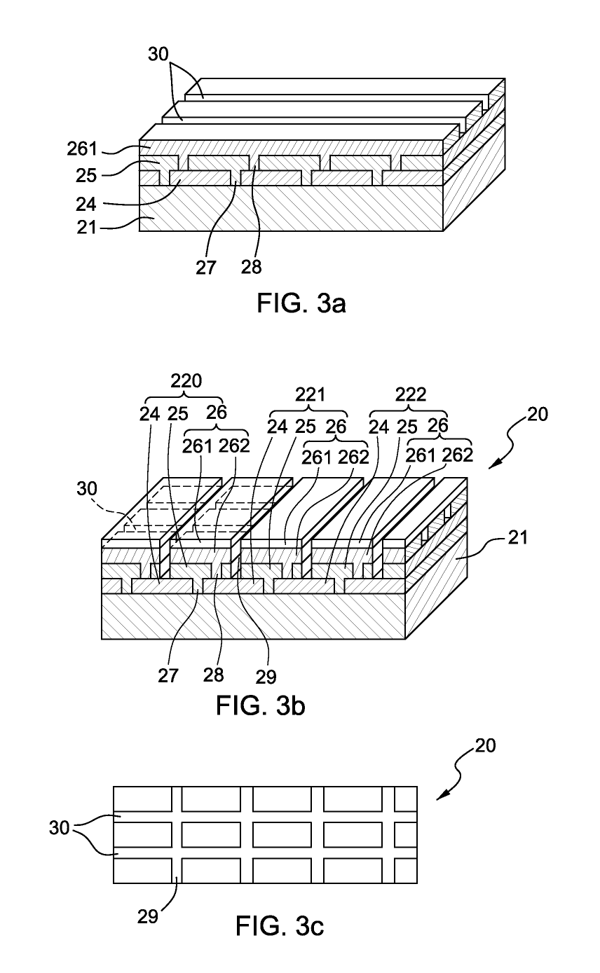

FIGS. 3(a) and 3(b) illustrate a process for making a partially transparent photovoltaic module according to one embodiment of the present invention. As shown in FIG. 3(a), the front electrodes 24, photoelectric conversion elements 25, and the first and second grooves 27 and 28 are formed on the substrate 21 according to any of the conventional processes; and a metal is disposed on the photoelectric conversion elements 25 and the second grooves 28, by screen printing, jet printing, roll-to-roll processing or depositing through a shadow mask with openings, so as to form a patterned metal layer 261 having a pattern with stripe-like openings 30. According to FIG. 3(b), after depositing a TCO layer without pattern (not shown in FIG. 3(a)) on said patterned metal layer, a conventional process, such as laser scribing is then used to form third grooves 29 to separate the adjacent back electrodes 26 and photoelectric conversion elements 25, and a partially transparent photovoltaic module 20 comprising a plurality of series-connected photovoltaic cells 220, 221 and 222 are produced. Therefore, the photovoltaic module 20 is composed of a plurality of series-connected photovoltaic cells 220, 221 and 222 disposed on a transparent substrate 21. Each of the photovoltaic cells comprises a front electrode 24, a photoelectric conversion element 25 and a patterned back electrode 26 composed of a patterned metal layer 261 and a TCO layer 262. FIG. 3(c) is a top view of the patterned metal layer 261 of the photovoltaic module 20 of FIG. 3(b). According to FIG. 3(c), each of the back electrodes 26 has a patterned metal layer 261 with stripe- like openings 30.

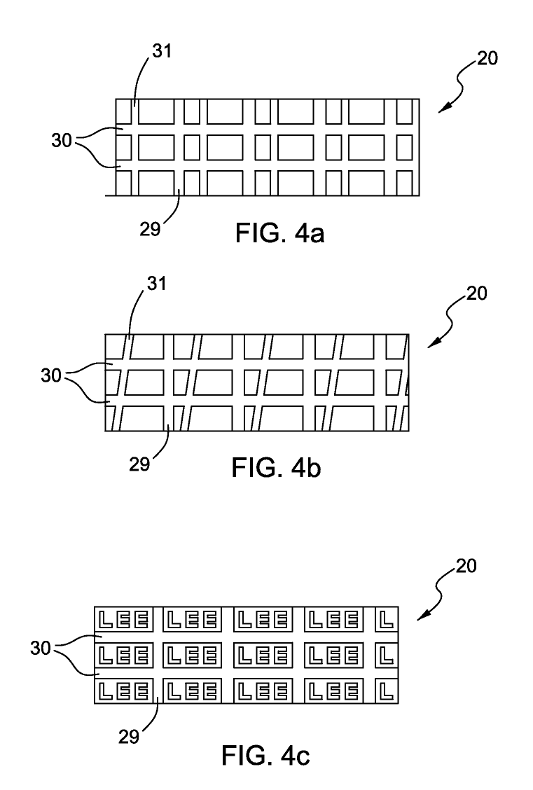

As stated above, the type of the pattern on the patterned metal layer is not specifically limited and can be various, such as web-like pattern, pattern with holes or pattern with linear or non-linear openings. According to another embodiment of the present invention, each of the back electrodes 26 of the partially transparent photovoltaic module has a patterned metal layer with stripe-like openings 30 in x-direction and stripe-like openings 31 in y-direction as shown in FIG. 4(a), or a patterned metal layer with stripe-like openings 30 and 31 in other directions as shown in FIG. 4(b), or a patterned metal layer with a trademark as shown in FIG. 4(c). In any cases, a TCO layer can be optionally used to keep the whole back electrode of each cell being electrically-connected or to reduce any other adverse effects.

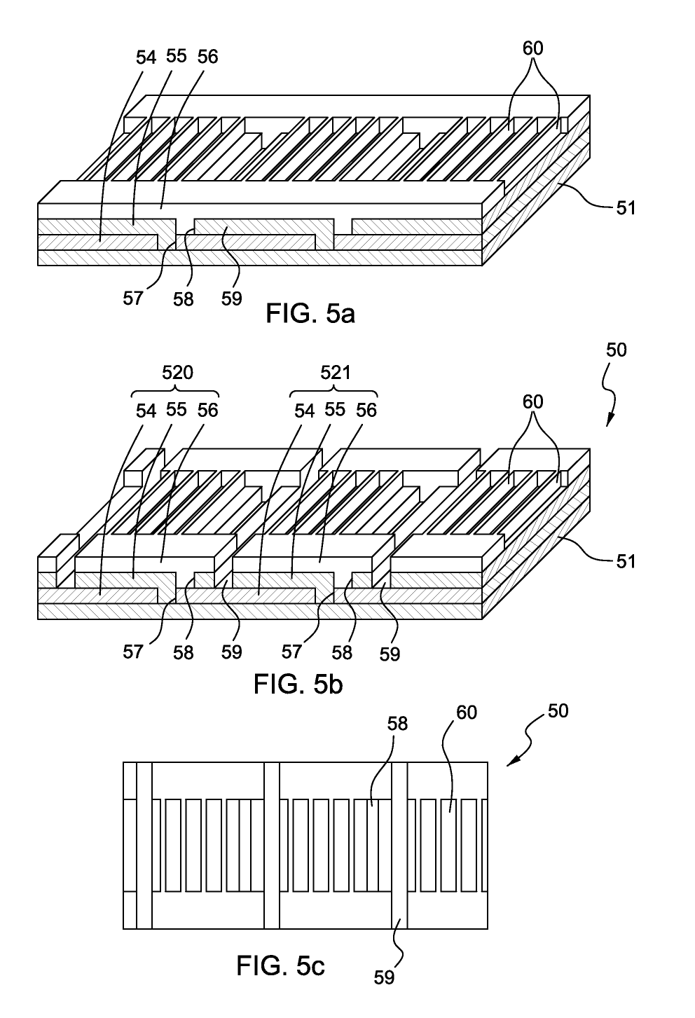

FIGS. 5(a) and 5(b) further illustrate a process for making a partially transparent photovoltaic module according to a further embodiment of the present invention. As shown in FIG. 5(a), the front electrodes 54, photoelectric conversion elements 55, and the first and second grooves 57 and 58 are formed on the substrate 51 according to any of the conventional processes; and a metal is disposed on the photoelectric conversion elements 55 and the second grooves 58, by screen printing, jet printing, roll-to-roll processing or depositing through a shadow mask with openings, so as to form a patterned back electrode 56 having a pattern with stripe-like openings 60. Then, as shown in FIG. 5(b), a conventional process, such as laser scribing is then used to form third grooves 59 to separate the adjacent back electrodes 56 and photoelectric conversion elements 55, and a partially transparent photovoltaic module 50 comprising a plurality of series-connected photovoltaic cells 520 and 521 are produced. According to FIG. 5(b), the photovoltaic module 50 is composed of a plurality of series-connected photovoltaic cells 520 and 521 disposed on a transparent substrate 51. Each of the photovoltaic cells comprises a front electrode 54, a photoelectric conversion element 55 and a patterned back electrode 56. FIG. 5(c) is a top view of the patterned back electrodes 56 of the photovoltaic module 50 of FIG. 5(b). According to FIG. 5(c), each of the patterned back electrodes 56 has stripe-like openings 60.

Although the above descriptions are directed to partially transparent photovoltaic module comprising a plurality of series-connected photovoltaic cells only, persons having ordinary skill will understand how to make a partially transparent photovoltaic module comprising parallel-connected photovoltaic cells on the basis of the disclosure of the present invention and their knowledge in the art.

According to one preferred embodiment, the present invention provides a process for making a partially transparent photovoltaic module comprising series-connected photovoltaic cells, said process comprising the steps of:

(a) providing a transparent substrate;

(b) forming transparent front electrodes on the substrate, wherein the transparent front electrodes are separated from each other by first grooves;

(c) forming photoelectric conversion elements on the transparent front electrodes and the first grooves, wherein the photoelectric conversion elements are separated from each other by second grooves disposed on the transparent front electrodes; and

(d) forming patterned back electrodes by screen printing, jet printing, roll-to-roll processing or depositing through a shadow mask with openings, wherein the patterned back electrodes are separated from each other by third grooves.

According to the present invention, the first and second grooves can be formed by depositing the transparent front electrodes and the photoelectric conversion elements through a shadow mask with openings. According to the present invention, the first and second grooves can also be formed by etching, mechanical scribing, electrical discharge scribing, and laser scribing the transparent front electrode layer or the photoelectric conversion layer or any other conventional methods. Laser scribing is preferred for making grooves having small width, i.e., less than 0.080 mm, and therefore, the loss of the photoelectric conversion efficiency can be reduced.

According to one embodiment of the present invention, the third grooves can be made at the same time when the patterned back electrodes are formed by screen printing, jet printing, roll-to-roll processing or depositing through a shadow mask with openings. According to another embodiment of the present invention, the third grooves can also be made by a conventional process, such as mechanical scribing, electrical discharge scribing and laser scribing, among which laser scribing is preferred.

Although the present invention has been described with reference to illustrative embodiments, it should be understand that any modifications or alterations that can easily be accomplished by persons skilled in the art will fall within the scope of the disclosure of the specification and the appended claims.

What is claimed is:

1. A process for making a partially transparent photovoltaic cell comprising a transparent front electrode, a photoelectric conversion element and a patterned back electrode disposed in order on a transparent substrate, said process comprising forming the patterned back electrode by screen printing, jet printing, roll-to-roll processing or depositing through a shadow mask with openings.

2. The process of claim 1, wherein the patterned back electrode is formed by depositing through a shadow mask with openings.

3. The process of claim 1, wherein the material of the patterned back electrode comprises a metal, a transparent conductive oxide (TCO), or a combination thereof.

4. The process of claim 1, wherein the patterned back electrode is composed of a pattered metal layer and an optionally transparent conductive oxide (TCO) layer.

5. The process of claim 1, wherein the patterned back electrode has web-like pattern, pattern with holes or pattern with linear or non-linear openings.

6. The process of claim 1, wherein the patterned back electrode is formed by depositing through a shadow mask with openings.

7. The process of claim 6, wherein a patterned back electrode is composed of a pattered metal layer and a transparent conductive oxide (TCO) layer, and wherein the pattered metal layer is formed by depositing through a shadow mask with openings and then a TCO layer is disposed on the patterned metal layer.

8. A process for making a partially transparent photovoltaic module comprising series-connected or parallel-connected photovoltaic cells, each of the photovoltaic cells comprising a transparent front electrode, a photoelectric conversion element and a patterned back electrode disposed in order on a transparent substrate, said process comprising forming the patterned back electrodes by screen printing, jet printing, roll-to-roll processing or depositing through a shadow mask with openings.

9. The process of claim 8, wherein the patterned back electrodes are formed by depositing through a shadow mask with openings.

10. The process of claim 8, wherein the material of each of the patterned back electrodes comprises a metal, a transparent conductive oxide (TCO), or a combination thereof.

11. The process of claim 8, wherein each of the patterned back electrodes is composed of a patterned metal layer and an optionally transparent conductive oxide (TCO) layer with or without pattern.

12. The process of claim 8, wherein the back electrodes have web-like pattern, pattern with holes or pattern with linear or non-linear openings.

13. A process for making a partially transparent photovoltaic module comprising series-connected photovoltaic cells, said process comprising the steps of:
(a) providing a transparent substrate;
(b) forming transparent front electrodes on the substrate, wherein the transparent front electrodes are separated from each other by first grooves;
(c) forming photoelectric conversion elements on the transparent front electrodes and the first grooves, wherein the photoelectric conversion elements are separated from each other by second grooves disposed on the transparent front electrodes; and
(d) forming patterned back electrodes by screen printing, jet printing, roll-to-roll processing or depositing through a shadow mask with openings, wherein the patterned back electrodes are separated from each other by third grooves.

14. The process of claim 13, wherein the patterned back electrodes are formed by depositing through a shadow mask with openings.

15. The process of claim 13, wherein the material of each of the patterned back electrodes comprises a metal, a transparent conductive oxide (TCO), or a combination thereof.

16. The process of claim 13, wherein each of the patterned back electrodes is composed of a patterned metal layer and an optionally transparent conductive oxide (TCO) layer.

17. The process of claim 13, wherein the patterned back electrodes have web-like pattern, pattern with holes or pattern with linear or non-linear openings.

18. The process of claim 13, wherein ether the first or second grooves or both are formed by laser scribing.

19. The process of claim 13, wherein the third grooves are made at the same time when the patterned back electrodes are formed by screen printing, jet printing, roll-to-roll processing or depositing through a shadow mask with openings; or made by laser scribing.
